(19) United States
(12) Patent Application Publication
(10) Pub. No.: US 2022/0158014 A1
(43) Pub. Date: May 19, 2022

(54) PHOTOVOLTAIC MODULES

(71) Applicant: Saudi Arabian Oil Company, Dhahran (SA)

(72) Inventors: Aziz Fihri, Paris (FR); Yassine Malajati, Beachwood, OH (US); Abdullatif Jazzar, Khobar (SA); Remi Mahfouz, Alkobra (SA)

(73) Assignee: Saudi Arabian Oil Company, Dhahran (SA)

(21) Appl. No.: 16/950,249

(22) Filed: Nov. 17, 2020

(51) Int. Cl. H01L 31/048; H01L 31/049; C08K 3/36

(52) U.S. Cl. CPC H01L 31/0481; H01L 31/049; C08K 2201/005; C08K 2201/011; C08K 3/36

(57) ABSTRACT

Photovoltaic modules include a front sheet, a back sheet, a photovoltaic layer, a first encapsulant layer, and a second encapsulant layer. The front sheet is made of or includes a composite of a thermoplastic material and a nanoparticle filler dispersed in the thermoplastic material. The thermoplastic material is a poly(methyl methacrylate) or a polycarbonate. The nanoparticle filler may include nanoparticles such as silica nanoparticles, titania nanoparticles, zirconia nanoparticles, zinc oxide nanoparticles, and combinations thereof, for example. The photovoltaic layer is interposed between the front sheet and the back sheet and includes at least one photovoltaic cell. The first encapsulant layer is interposed between the front sheet and the at least one photovoltaic cell. The second encapsulant layer is interposed between the at least one photovoltaic cell and the back sheet.

### TECHNICAL FIELD

The present application relates generally to photovoltaic modules and, more particularly, to photovoltaic modules including polymeric front sheets.

### BACKGROUND

Capturing solar energy through photovoltaic panels to produce electricity is considered as one of the most promising applications in the renewable energy sector. The current photovoltaic market is dominated by rigid, crystalline, silicon-based photovoltaic systems typically including photovoltaic cells overlain by a front sheet of a transparent glass. The function of the front sheet is to protect the photovoltaic cell from impact, abrasion, or any external force. For such photovoltaic modules, the glass front sheets add significant weight to the module and are prone to shattering and scratching. Therefore, in addition to functional concerns about decreased photovoltaic output from damaged glass, safety issues arise with respect to storing, transporting, installing, or replacing the front sheets. Accordingly, ongoing needs exist for materials suitably transparent for inclusion within photovoltaic modules while also having sufficient resistance to scratching and shattering.

### SUMMARY

Against the above background, embodiments of this disclosure are directed to photovoltaic modules. The photovoltaic modules include a front sheet, a back sheet, a photovoltaic layer, a first encapsulant layer, and a second encapsulant layer. The front sheet is made of or includes a composite of a thermoplastic material and a nanoparticle filler dispersed in the thermoplastic material. The thermoplastic material is a poly(methyl methacrylate) or a polycarbonate. In some embodiments, the nanoparticle filler may include nanoparticles such as silica nanoparticles, titania nanoparticles, zirconia nanoparticles, zinc oxide nanoparticles, and combinations thereof, for example. The photovoltaic layer is interposed between the front sheet and the back sheet and includes at least one photovoltaic cell. The first encapsulant layer is interposed between the front sheet and the at least one photovoltaic cell. The second encapsulant layer is interposed between the at least one photovoltaic cell and the back sheet.

These and other features, aspects, and advantages will become better understood with reference to the following description and the appended claims.

Additional features and advantages of the embodiments described herein will be set forth in the detailed description that follows, and in part will be readily apparent to those skilled in the art from that description or recognized by practicing the embodiments described herein, including the following detailed description, the claims, and the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 is an exploded view of a photovoltaic module according to embodiments herein.

FIG. 2 is cross section of a photovoltaic module according to embodiments herein.

FIG. 3 is a perspective view of an example photovoltaic cell as a component of a photovoltaic layer in a photovoltaic module according to embodiments herein.

### DETAILED DESCRIPTION

Reference will now be made in detail to embodiments of photovoltaic modules. The photovoltaic modules include polymeric front sheets that decrease overall weight of the photovoltaic module, relative to photovoltaic modules including primarily glass constructions, without substantially sacrificing optical transparency or device output capability.

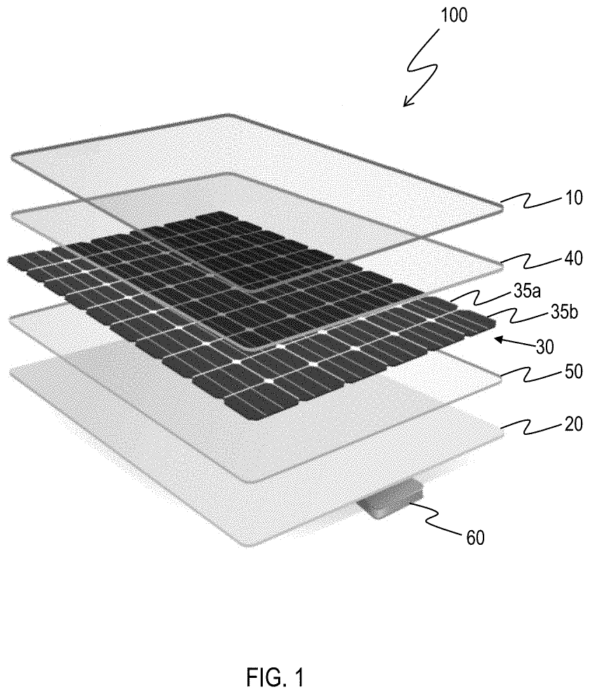

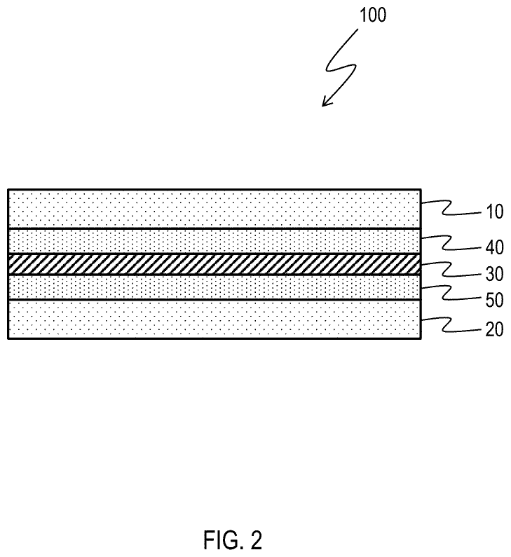

Referring to FIGS. 1 and 2, a photovoltaic module 100 according to embodiments include a front sheet 10 and a back sheet 20. A photovoltaic layer 30 is interposed between the front sheet 10 and the back sheet 20. The photovoltaic layer 30 includes at least one photovoltaic cell 35a, 35b. A first encapsulant layer 40 is interposed between the front sheet 10 and the photovoltaic layer 30. A second encapsulant layer 50 is interposed between the photovoltaic layer 30 and the back sheet 20. Thus, in embodiments, the photovoltaic layer 30 may be encapsulated between the first encapsulant layer 40 and the second encapsulant layer 50. It should be understood that the arrangement, geometric configuration, and total number of photovoltaic cells constituting the at least one photovoltaic cell 35a, 35b in the photovoltaic layer 30 in FIG. 1 are provided as an example only and that numerous other configurations are possible. Moreover, for the sake of simplicity, only two photovoltaic cells 35a, 35b have been labeled in FIG. 1, though the entire photovoltaic layer 30 of FIG. 1 includes sixty such photovoltaic cells arranged in six rows of ten individual photovoltaic cells.

In the photovoltaic module 100 according to embodiments, the front sheet 10 protects the photovoltaic cells of the photovoltaic layer 10 from impacts, abrasion, or external forces. The first encapsulant layer 40 and the second encapsulant layer 50 function as adhesive layers that bind the photovoltaic layer 30 to the front sheet 10 and the back sheet 20, while also dampening mechanical shocks that are transmitted through the photovoltaic layer 30 and acting as a sealant to prevent any moisture or dirt from contaminating the photovoltaic cells in the photovoltaic layer 30. Finally, the function of the back sheet 20 is to provide protection from external mechanical stresses while acting as an electrical insulator. The photovoltaic module 100 may include any suitable means for establishing electrical connection of the photovoltaic module 100 with an external electrical device such as an energy storage device, battery, electric circuit, or electrical load. In the embodiment of FIG. 1, for example, the photovoltaic module 100 includes a junction box 60, to which any electrical connection from the photovoltaic layer 30 may be joined to an external electrical device (not shown). In embodiments, the photovoltaic layer 30 may include electrical contacts to the at least one photovoltaic cell 35, and the electrical contacts are configured to be placed in electrical continuity with an external energy storage device or an electrical load.

In the photovoltaic module 100 according to embodiments, the front sheet 10 includes, or is made from, a composite of a thermoplastic material and a nanoparticle filler dispersed in the thermoplastic material. The thermoplastic material may be a poly(methyl methacrylate) or a polycarbonate. Compared to inorganic glass, the transparent polymers poly(methyl methacrylate) and polycarbonate have lighter weight, greater impact resistance, and good processability. However, virgin poly(methyl methacrylate) and virgin polycarbonate generally have several limitations such as low resistance to scratching. Therefore, in embodiments, the composite further includes the nanoparticle filler dispersed in the thermoplastic material. The nanoparticle filler significantly increases the respective impact strengths, Young's modulus, and hardness of the thermoplastic material.

In embodiments, the nanoparticle filler may include nanoparticles such as, for example, silica nanoparticles, titania nanoparticles, zirconia nanoparticles, zinc oxide nanoparticles, and combinations of these. The composite may include from 0.5% to 5% by weight nanoparticle filler, based on the total weight of the composite. The nanoparticles of the nanoparticle filler may include any size of nanoparticles that increase the mechanical characteristics of the thermoplastic without substantially lessening the transparency of the thermoplastic material. In embodiments, the nanoparticles of the nanoparticle filler may have particle sizes from 7 nm to 50 nm, for example. In embodiments, the composite may have a transmittance to light at 500 nm of 80% to 95%, or from 85% to 92%. In embodiments, the composite has a density from 1.1 g/cm³ to 1.2 g/cm³ or from 1.14 g/cm³ to 1.2 g/cm³, compared to typical inorganic glasses that typically have densities of 2.5 g/cm³.

In the photovoltaic module 100 according to embodiments, the photovoltaic layer 30 is interposed between the front sheet 10 and the back sheet 20 and includes at least one photovoltaic cell 35a, 35b. In embodiments, the photovoltaic layer 30 includes a plurality of photovoltaic cells arranged in a suitable matrix to maximize a surface area for capturing incident solar radiation to produce electricity. For example, the photovoltaic layer 30 may include as few as one photovoltaic cell or as many as two photovoltaic cells, 50 photovoltaic cells, 100 photovoltaic cells, 1000 photovoltaic cells, 10,000 photovoltaic cells, 50,000 photovoltaic cells, 100,000 photovoltaic cells, or greater than 100,000 photovoltaic cells.

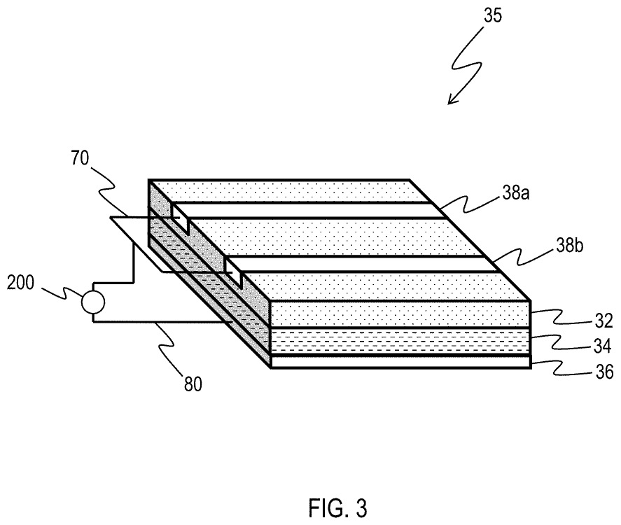

Referring to FIG. 3, an example of an individual photovoltaic cell 35 according to embodiments may be configured as a p-n junction including a first semiconductor layer 32 and a second semiconductor layer 34. In some embodiments, the first semiconductor layer 32 may be a p-type semiconductor and the second semiconductor layer 34 may be an n-type semiconductor. In other embodiments, the first semiconductor layer 32 may be an n-type semiconductor and the second semiconductor layer 34 may be a p-type semiconductor. The individual photovoltaic cell includes a lower contact layer 36 and upper contact traces 38a, 38b. Though the embodiment of FIG. 3 includes two upper contact traces 38a, 38b, it should be understood that only one contact trace may be present or that greater than two contact traces may be present. The dimensions and geometry of the upper contact traces 38a, 38b may vary in any practical manner that enables sufficient ability for the photovoltaic cell 35 to convey electrons into the contact traces while not substantially lessening the surface area of the photovoltaic cell that can be exposed to incident radiation for generation of electricity. The upper contact traces 38a, 38b may be in electrical contact with corresponding upper contact traces of adjacent photovoltaic cells within the photovoltaic module 100. For at least one photovoltaic cell 35 of the photovoltaic module 100, the upper contact traces 38a, 38b are electrically connected to a first lead 70 that establishes electrical connection of the upper contact traces 38a, 38b of the photovoltaic cell 35 or of multiple photovoltaic cells to a load element 200.

In some embodiments, the load element 200 may be an energy storage device such as a battery, for example. In other embodiments, the load element 200 may be any electrical circuit or device that uses electricity generated by the photovoltaic module 100 to function in any manner. It should be understood, therefore, that the load element 200 as depicted in FIG. 3 is presented schematically only and that the load element 200 may represent a single simple device or a highly complex electrical configuration including multiple electrical devices.

The lower contact layer 36 may be any electrically conductive element such as a wire, a conductive strip, or a conductive foil, for example. The lower contact layer 36 may have electrical contact with any portion of the second semiconductor layer 34 or may contact or cover a large portion of the surface, or even substantially the entire surface, of the second semiconductor layer 34. The lower contact layer 36 may be in electrical continuity with corresponding lower contact layers of adjacent photovoltaic cells within the photovoltaic module 100. For at least one photovoltaic cell 35 of the photovoltaic module 100, the lower contact layer 36 is electrically connected to a second lead 80 that establishes electrical connection of the lower contact layer 36 of the photovoltaic cell 35 or of multiple photovoltaic cells to the load element 200, thereby establishing a complete circuit across the p-n junction between the first semiconductor layer 32 and the second semiconductor layer 34.

The at least one photovoltaic cell 35 of the photovoltaic layer 30 may be any type of photovoltaic cell capable of generating electricity upon exposure to electromagnetic radiation such as solar radiation. Example materials that may be included in a photovoltaic cell 35 according to embodiments include polycrystalline silicon, monocrystalline silicon, cadmium sulfide, cadmium selenide, cadmium telluride, indium phosphide, gallium arsenide, copper (I) sulfide, copper indium gallium diselenide, or combinations or multilayers of any of these materials.

In the photovoltaic module 100 according to embodiments, the photovoltaic layer 30 is interposed between the first encapsulant layer 40 and the second encapsulant layer 50. The first encapsulant layer 40 is interposed between the front sheet 10 and the photovoltaic layer 30. Likewise, the second encapsulant layer is interposed between the photovoltaic layer 30 and the back sheet 20. Both the first encapsulant layer 40 and the second encapsulant layer 50 include or consist of an encapsulant material. The encapsulant material of the first encapsulant layer 40 may be the same as or different from the encapsulant material of the second encapsulant layer 50. The encapsulant material may be selected from any polymer or adhesive material known in the art of photovoltaic modules as being suitable for encapsulating or protecting photovoltaic cells with sufficient transparency. In example embodiments, suitable encapsulant materials for the first encapsulant layer 40, the second encapsulant layer 50, or both, include ethylene(vinyl acetate), poly(vinyl butyral), polyolefins and thermoplastic polyolefins, thermoplastic polyurethanes, silicones, and ionomers. In specific embodiments, the first encapsulant layer 40 and the second encapsulant layer 50 are sheets of ethylene vinyl acetate or thermoplastic olefin.

In a specific example embodiment, the photovoltaic module 100 may include the front sheet 10 of a composite in which the thermoplastic material is a poly(methyl methacrylate) and the nanoparticle filler includes silica nanoparticles. In another specific example embodiment, the photovoltaic module 100 may include the front sheet 10 of a composite including from 0.5% to 5% by weight nanoparticle filler, based on the total weight of the composite, and in which the thermoplastic material is a poly(methyl methacrylate), the nanoparticle filler is or include silica nanoparticles, the composite has a density from 1.14 g/cm³ to 1.2 g/cm³, and the composite has a transmittance of 80% to 92% at 500 nanometers.

The photovoltaic module 100 according to embodiments includes the back sheet 20. The back sheet 20 may be made from any material, composite, or laminate commonly used in the art of photovoltaic devices as a backing layer that provides protection from external mechanical stresses and electrical insulation. Optionally, the back sheet 20 may be coated with an ultraviolet-protective coating.

In example embodiments, the back sheet 20 may include a poly(vinyl fluoride), a poly(vinylidene fluoride), a polyester, a poly(vinyl acetate), a poly(ethylene terephthalate), a poly(methyl methacrylate), or a polycarbonate. Examples of composite or multilayer materials suitable as the back sheet include poly(vinyl fluoride)-polyester-poly(vinyl fluoride) laminates, poly(vinyl fluoride)-polyester-ethylene vinyl acetate laminates, poly(vinylidene fluoride)-polyester-poly(vinylidene fluoride) laminates, and poly(vinylidene fluoride)-polyester-ethylene vinyl acetate laminates. Several such laminates are commercially available that include materials such as Tedlar® or Kynar®. Tedlar® is a poly(vinyl fluoride) manufactured by DuPont™ with a CAS Registry number of 24981-14-4. Kynar® is a poly(vinylidene fluoride) material manufactured by Arkema. Commercially available laminates of these materials include three-layer materials such as Tedlar® Polyester Tedlar® (TPT), Tedlar® Polyester EVA (TPE), Kynar® Polyester EVA (KPE), and Kynar® Polyester Kynar® (KPK).

In some embodiments, the back sheet 20 may include polymer materials that are nanoparticle-filled or include nanoparticles as fillers for mechanical stability or enhancement. Examples of nanoparticle-filled materials include nanoparticle-filled poly(methyl methacrylate) and nanoparticle-filled polycarbonate. In one specific embodiment, the back sheet 20 may be made from the same material as the front-sheet, namely, from a composite of poly(methyl methacrylate) or polycarbonate including a nanoparticle filler.

In example embodiments of the photovoltaic module 100, the thicknesses of the individual layers, as well as the thickness ratios of each layer to the other layers, may be varied according to a desired structure and application. In non-limiting example embodiments, the photovoltaic module 100 may include a front sheet 10 with a thickness from 1.5 mm to 3.5 mm, a back sheet 20 with a thickness from 0.1 mm to 0.5 mm, a photovoltaic layer 30 with a thickness from 0.1 mm to 0.5 mm, a first encapsulant layer 40 with a thickness from 0.2 mm to 0.4 mm, and a second encapsulant layer 50 with a thickness from 0.2 mm to 0.4 mm.

As previously described, the front sheet 10 of the photovoltaic module 100 is a nanoparticle-filled polymeric composite. In some embodiments, even beyond the polymeric, non-glass front sheet 10, the photovoltaic module 100 is free of glass components. That is, in some embodiments, none of the front sheet 10, the back sheet 20, the photovoltaic layer 30, the first encapsulant layer 40, and the second encapsulant layer 50 is an inorganic glass material.

The photovoltaic modules according to embodiments may be assembled by common methods for preparing photovoltaic devices. For example, the individual layers such as the front sheet 10, the back sheet 20, the photovoltaic layer 30, the first encapsulant layer 40, and the second encapsulant layer 50 may be stacked in the proper order as in FIG. 1. To the stacked layer, heat, pressure, or both may be applied under conditions appropriate to enable the first encapsulant layer 40 and the second encapsulant layer 50 to adhere the front sheet 10 and the back sheet 20 to the photovoltaic layer 30, thereby forming a stable, laminated structure. The photovoltaic module 100 optionally may be mounted or further protected in an outer frame to prepare the photovoltaic module 100 for operation.

Unless otherwise defined, all technical and scientific terms used herein have the same meaning as commonly understood by one of ordinary skill in the art to which the invention belongs. The terminology used in the description herein is for describing particular embodiments only and is not intended to be limiting. As used in the specification and appended claims, the singular forms “a,” “an,” and “the” are intended to include the plural forms as well, unless the context clearly indicates otherwise.

### Examples

The embodiments described herein will be better understood by reference to the following example, which is offered by way of illustration and which one skilled in the art will recognize is not meant to be limiting.

A photovoltaic module according to FIG. 1 is prepared by laminating a front sheet, a first encapsulant layer, a photovoltaic layer, a second encapsulant layer, and a back sheet to form a multilayer structure. A front sheet for the photovoltaic module was prepared and submitted to mechanical testing. The front sheet was a composite of a poly(methyl methacrylate) including 1% by weight silica nanoparticles as a nanoparticle filler dispersed in the poly(methyl methacrylate). The silica nanoparticles had particle sizes from about 7 nm to about 50 nm.

The front sheet was determined by spectrophotometry to have a transmittance of 87.03% at 500 nm. The front sheet had a density of 1.2 g/cm³ at 25° C.

Scratch resistance of the front sheet was determined according to ASTM D3363-05 using a pencil scratch tester with a load of 500 grams, a pencil angle of 45 degrees, and a scratch speed of 1 millimeter per second. The pencil scratch test correlates scratch resistance to the hardnesses of various grades of graphite pencils. Graphite pencils are classified by a standard scale in which 10B represents the softest graphite and 10H represents the hardest graphite. The full scale from softest to hardest is 10B, 9B, 8B, 7B, 6B, 5B, 4B, 3B, 2B, 1B, HB, F, 1H, 2H, 3H, 4H, 5H, 6H, 7H, 8H, 9H, 10H.

By the scratch resistance test, the front sheet of the present example had a hardness of 1B. A comparative sample of virgin poly(methyl methacrylate), not including any nanoparticle filler, was tested in the same manner and had a hardness of only 5B. Thus, the front sheet including 1% by weight silica nanoparticle filler has a significantly greater resistance to scratching, compared to the virgin poly(methyl methacrylate) without nanoparticle filler.

### Items Listing

Embodiments of the present disclosure include at least following items, which are not intended to limit the scope of the disclosure as a whole or of the appended claims.

Item 1: A photovoltaic module comprising: a front sheet comprising a composite of a thermoplastic material and a nanoparticle filler dispersed in the thermoplastic material, wherein the thermoplastic material is a poly(methyl methacrylate) or a polycarbonate; a back sheet; a photovoltaic layer interposed between the front sheet and the back sheet, the photovoltaic layer comprising at least one photovoltaic cell; a first encapsulant layer interposed between the front sheet and the at least one photovoltaic cell; and a second encapsulant layer interposed between the at least one photovoltaic cell and the back sheet.

Item 2: The photovoltaic module of Item 1, wherein the nanoparticle filler comprises nanoparticles selected from silica nanoparticles, titania nanoparticles, zirconia nanoparticles, zinc oxide nanoparticles, and combinations thereof.

Item 3: The photovoltaic module of Item 1 or 2, wherein the composite comprises from 0.5% to 5% by weight nanoparticle filler, based on the total weight of the composite.

Item 4: The photovoltaic module of any of the preceding Items, wherein the nanoparticle filler consists of nanoparticles having particle sizes from 7 nm to 50 nm.

Item 5: The photovoltaic module of any of the preceding Items, wherein the composite has a transmittance of 80% to 92% at 500 nanometers.

Item 6: The photovoltaic module of any of the preceding Items, wherein the composite has a density from 1.14 g/cm³ to 1.2 g/cm³.

Item 7: The photovoltaic module of any of the preceding Items, wherein the nanoparticle filler comprises silica nanoparticles having particle sizes from 7 nm to 50 nm.

Item 8: The photovoltaic module of any of the preceding Items, wherein: the thermoplastic material is a poly(methyl methacrylate); and the nanoparticle filler comprises silica nanoparticles.

Item 9: The photovoltaic module of any of the preceding Items, wherein: the composite comprises from 0.5% to 5% by weight nanoparticle filler, based on the total weight of the composite; the thermoplastic material is a poly(methyl methacrylate); the nanoparticle filler comprises silica nanoparticles; the composite has a density from 1.14 g/cm³ to 1.2 g/cm³; and the composite has a transmittance of 80% to 92% at 500 nanometers.

Item 10: The photovoltaic module of any of the preceding Items, wherein the back sheet is selected from poly(vinyl fluoride)-polyester-poly(vinyl fluoride) laminate, poly(vinyl fluoride)-polyester-ethylene vinyl acetate laminate, poly(vinylidene fluoride)-polyester-poly(vinylidene fluoride) laminate, poly(vinylidene fluoride)-polyester-ethylene vinyl acetate laminate, poly(ethylene terephthalate), virgin poly(methyl methacrylate), virgin polycarbonate, nanoparticle-filled poly(methyl methacrylate), or nanoparticle-filled polycarbonate.

Item 11: The photovoltaic module of any of the preceding Items, wherein the back sheet comprises poly(methyl methacrylate) or polycarbonate.

Item 12: The photovoltaic module of any of the preceding Items, wherein the back sheet comprises nanoparticle-filled poly(methyl methacrylate) or nanoparticle-filled polycarbonate.

Item 13: The photovoltaic module of any of the preceding Items, wherein the back sheet is selected from poly(vinyl fluoride)-polyester-poly(vinyl fluoride) laminate, poly(vinyl fluoride)-polyester-ethylene vinyl acetate laminate, poly(vinylidene fluoride)-polyester-poly(vinylidene fluoride) laminate, or poly(vinylidene fluoride)-polyester-ethylene vinyl acetate laminate.

Item 14: The photovoltaic module of any of the preceding Items, wherein the back sheet comprises poly(ethylene terephthalate).

Item 15: The photovoltaic module of any of the preceding Items, wherein the back sheet is coated with an ultraviolet-protective coating.

Item 16: The photovoltaic module of any of the preceding Items, wherein the at least one photovoltaic cell comprises polycrystalline silicon, monocrystalline silicon, cadmium sulfide, cadmium selenide, cadmium telluride, indium phosphide, gallium arsenide, copper (I) sulfide, or copper indium gallium diselenide.

Item 17: The photovoltaic module of any of the preceding Items, wherein the first encapsulant layer and the second encapsulant layer are selected from ethylene vinyl acetate and thermoplastic olefin.

Item 18: The photovoltaic module of any of the preceding Items, wherein: the front sheet has a thickness from 1.5 mm to 3.5 mm; the back sheet has a thickness from 0.1 mm to 0.5 mm; the photovoltaic layer has a thickness from 0.1 mm to 0.5 mm; a first encapsulant layer has a thickness from 0.2 mm to 0.4 mm; and a second encapsulant layer has a thickness from 0.2 mm to 0.4 mm.

Item 19: The photovoltaic module of any of the preceding Items, wherein the photovoltaic layer further comprises electrical contacts to the at least one photovoltaic cell configured to be placed in electrical continuity with an energy storage device or an electrical load.

Item 20: The photovoltaic module of any of the preceding Items, wherein the photovoltaic module is free of glass components.

It is noted that the terms “substantially” and “about” may be used herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue.

What is claimed is:

1. A photovoltaic module comprising:
a front sheet comprising a composite of a thermoplastic material and a nanoparticle filler dispersed in the thermoplastic material, wherein the thermoplastic material is a poly(methyl methacrylate) or a polycarbonate;
a back sheet;
a photovoltaic layer interposed between the front sheet and the back sheet, the photovoltaic layer comprising at least one photovoltaic cell;
a first encapsulant layer interposed between the front sheet and the at least one photovoltaic cell; and
a second encapsulant layer interposed between the at least one photovoltaic cell and the back sheet.

2. The photovoltaic module of claim 1, wherein the nanoparticle filler comprises nanoparticles selected from silica nanoparticles, titania nanoparticles, zirconia nanoparticles, zinc oxide nanoparticles, and combinations thereof.

3. The photovoltaic module of claim 1, wherein the composite comprises from 0.5% to 5% by weight nanoparticle filler, based on the total weight of the composite.

4. The photovoltaic module of claim 1, wherein the nanoparticle filler consists of nanoparticles having particle sizes from 7 nm to 50 nm.

5. The photovoltaic module of claim 1, wherein the composite has a transmittance of 80% to 92% at 500 nanometers.

6. The photovoltaic module of claim 1, wherein the composite has a density from 1.14 g/cm³ to 1.2 g/cm³.

7. The photovoltaic module of claim 1, wherein the nanoparticle filler comprises silica nanoparticles having particle sizes from 7 nm to 50 nm.

8. The photovoltaic module of claim 1, wherein:
the thermoplastic material is a poly(methyl methacrylate); and
the nanoparticle filler comprises silica nanoparticles.

9. The photovoltaic module of claim 1, wherein:
the composite comprises from 0.5% to 5% by weight nanoparticle filler, based on the total weight of the composite;
the thermoplastic material is a poly(methyl methacrylate);
the nanoparticle filler comprises silica nanoparticles;
the composite has a density from 1.14 g/cm³ to 1.2 g/cm³; and
the composite has a transmittance of 80% to 92% at 500 nanometers.

10. The photovoltaic module of claim 1, wherein the back sheet is selected from poly(vinyl fluoride)-polyester-poly(vinyl fluoride) laminate, poly(vinyl fluoride)-polyester-ethylene vinyl acetate laminate, poly(vinylidene fluoride)-polyester-poly(vinylidene fluoride) laminate, poly(vinylidene fluoride)-polyester-ethylene vinyl acetate laminate, poly(ethylene terephthalate), virgin poly(methyl methacrylate), virgin polycarbonate, nanoparticle-filled poly(methyl methacrylate), or nanoparticle-filled polycarbonate.

11. The photovoltaic module of claim 1, wherein the back sheet comprises poly(methyl methacrylate) or polycarbonate.

12. The photovoltaic module of claim 1, wherein the back sheet comprises nanoparticle-filled poly(methyl methacrylate) or nanoparticle-filled polycarbonate.

13. The photovoltaic module of claim 1, wherein the back sheet is selected from poly(vinyl fluoride)-polyester-poly(vinyl fluoride) laminate, poly(vinyl fluoride)-polyester-ethylene vinyl acetate laminate, poly(vinylidene fluoride)-polyester-poly(vinylidene fluoride) laminate, or poly(vinylidene fluoride)-polyester-ethylene vinyl acetate laminate.

14. The photovoltaic module of claim 1, wherein the back sheet comprises poly(ethylene terephthalate).

15. The photovoltaic module of claim 1, wherein the back sheet is coated with an ultraviolet-protective coating.

16. The photovoltaic module of claim 1, wherein the at least one photovoltaic cell comprises polycrystalline silicon, monocrystalline silicon, cadmium sulfide, cadmium selenide, cadmium telluride, indium phosphide, gallium arsenide, copper (I) sulfide, or copper indium gallium diselenide.

17. The photovoltaic module of claim 1, wherein the first encapsulant layer and the second encapsulant layer are selected from ethylene vinyl acetate and thermoplastic olefin.

18. The photovoltaic module of claim 1, wherein:
the front sheet has a thickness from 1.5 mm to 3.5 mm;
the back sheet has a thickness from 0.1 mm to 0.5 mm;
the photovoltaic layer has a thickness from 0.1 mm to 0.5 mm;
a first encapsulant layer has a thickness from 0.2 mm to 0.4 mm; and
a second encapsulant layer has a thickness from 0.2 mm to 0.4 mm.

19. The photovoltaic module of claim 1, wherein the photovoltaic layer further comprises electrical contacts to the at least one photovoltaic cell configured to be placed in electrical continuity with an energy storage device or an electrical load.

20. The photovoltaic module of claim 1, wherein the photovoltaic module is free of glass components.
